(19) United States
(12) Patent Application Publication
(10) Pub. No.: US 2019/0035666 A1
(43) Pub. Date: Jan. 31, 2019

(54) SUBSTRATE PROCESSING APPARATUS

(71) Applicant: WONIK IPS CO., LTD., Gyeonggi-do (KR)

(72) Inventors: Sung Soon LIM, Gyeonggi-do (KR); Yong Baek JEON, Gyeonggi-do (KR); Doo Ho YANG, Gyeonggi-do (KR); Kyu Tae CHO, Gyeonggi-do (KR); Jae Hoon CHO, Gyeonggi-do (KR); Ji Su KIM, Gyeonggi-do (KR)

(21) Appl. No.: 16/044,625

(22) Filed: Jul. 25, 2018

(30) Foreign Application Priority Data
Jul. 25, 2017 (KR) 10-2017-0094388

(51) Int. Cl. H01L 21/683; H01L 21/67; H01J 37/32; H01L 21/3065

(52) U.S. Cl. CPC H01L 21/6831; H01L 21/67069; H01J 2237/334; H01L 21/3065; H01L 21/67207; H01J 37/32174

(57) ABSTRACT

The present invention provides a substrate processing apparatus for controlling a plasma environment on a substrate. The substrate processing apparatus comprises: a process chamber which defines a process space therein; a gas injection unit which is installed in the process chamber and supplies a process gas to the process space; an electrostatic chuck which is installed in the process chamber to be opposite to the gas injection unit and includes an electrostatic electrode for applying electrostatic force to the substrate mounted on the electrostatic chuck; a plasma power supply unit which includes at least one RF power source for applying at least one RF power to the gas injection unit in order to form a plasma atmosphere within the process chamber; an electrostatic power supply unit which includes a DC power source to supply DC power to the electrostatic electrode; and an electrostatic chuck current control circuit unit which is connected to the electrostatic electrode in parallel with the electrostatic electrode power supply unit in order to control a plasma atmosphere between the gas injection unit and the electrostatic chuck.

### CROSS-REFERENCE TO RELATED PATENT APPLICATION

This application claims the benefit of Korean Patent Application No. 10-2017-0094388, filed on Jul. 25, 2017, in the Korean Intellectual Property Office, the disclosure of which is incorporated herein in its entirety by reference.

### FIELD

The present invention relates to a semiconductor manufacturing, and more particularly to a substrate processing apparatus using plasma.

### DESCRIPTION OF RELATED ART

Processes using plasma are employed in the manufacture of semiconductor devices. For example, processes such as deposition or etching can be carried out at a high rate even at a low process temperature by activating a process gas with plasma. In such a substrate processing apparatus using plasma, it is important to control the plasma environment such as control of plasma matching according to process chambers, control of process variables such as gas amount, pressure, and the like.

However, in the case of the plasma control, although the impedance matching based on the condition of the process chamber could stabilize the plasma environment in the process chamber, there still was a limitation to optimize the electric current flowing onto the substrate because the process chamber was entirely grounded. In particular, it is required to precisely control the plasma environment onto the substrate in consideration of electrostatic force in the substrate processing apparatus using an electrostatic chuck.

### SUMMARY

The present invention is to solve various problems including the problem as mentioned above, and it is an object of the present invention to provide a substrate processing apparatus which is capable of controlling process conditions by controlling a plasma environment on a substrate in consideration of electrostatic force. However, this object is exemplary one and do not limit the scope of the present invention.

A substrate processing apparatus according to one aspect of the present invention for achieving the objects, comprising: a process chamber which defines a process space therein; a gas injection unit which is installed in the process chamber and supplies a process gas to the process space; an electrostatic chuck which is installed in the process chamber to be opposite to the gas injection unit and includes an electrostatic electrode for applying electrostatic force to a substrate mounted on the electrostatic chuck; a plasma power supply unit which includes at least one RF power source for applying at least one RF power to the gas injection unit in order to form a plasma atmosphere within the process chamber; an impedance matching unit which is connected between the plasma power supply unit and the gas injection unit for impedance matching between the at least one RF power source and the process chamber; an electrostatic power supply unit which includes a DC power source to supply DC power to the electrostatic electrode; and an electrostatic chuck current control circuit unit which is connected to the electrostatic electrode in parallel with the electrostatic electrode power supply unit, and passes at least one RF power current which is generated by the at least one RF power source and flows through the electrostatic electrode, while blocking DC current flowed thereinto from the electrostatic power supply unit, in order to control a plasma atmosphere between the gas injection unit and the electrostatic chuck.

In the substrate processing apparatus, the electrostatic chuck current control circuit unit may include at least one RF filter for passing the at least one RF current and at least one DC blocking element for blocking the DC current.

In the substrate processing apparatus, the at least one RF power source may include a first RF power source of a first frequency band, and a second RF power source of a second frequency band which is greater than the first frequency band, and the electrostatic chuck current control circuit unit may include a first RF filter for passing at least a first RF current of the first frequency band, a second RF filter for passing at least a second RF current of the second frequency band, and at least one capacitor for blocking the DC current.

In the substrate processing apparatus, the first RF power source may be a low frequency (LF) power source in which the first frequency band includes at least 370 kHz, the second RF power source may be a high frequency (HF) power source in which the second frequency band includes at least 27.12 MHz, the at least one capacitor may include a first capacitor which is connected in series between the electrostatic electrode and the first RF filter, and the serial connection structure of the first RF filter and the first capacitor may be connected in parallel with the second RF filter.

In the substrate processing apparatus, the first RF filter may include a band rejection filter for passing the remaining RF current except for the second RF current, and the second RF filter may include a bandpass filter for blocking the DC current while passing the second RF current.

In the substrate processing apparatus, the first RF filter may include a first inductor and a second capacitor which are connected in parallel to each other, and the second RF filter may include a second inductor and a third capacitor which are connected in series with each other.

In the substrate processing apparatus, the first RF filter may include a fourth capacitor which is connected in series between the ground and the parallel connection structure of the first inductor and the second capacitor.

In the substrate processing apparatus, the electrostatic power supply unit may include a DC filter which is disposed between the electrostatic electrode and the DC power source to block the at least one RF current through the electrostatic electrode from entering the DC power source.

In the substrate processing apparatus, the electrostatic chuck may include a heater for heating the substrate, and a heater power source which is connected to the heater to apply AC power to the heater and a third RF filter which is connected between the heater power source and the heater may be further provided.

According to some embodiments of the present invention configured as described above, it is possible to control the RF current flowing to the electrostatic chuck through the electrostatic electrode while avoiding interference with the electrostatic force, thereby controlling the plasma environment on the substrate. However, the scope of the present invention is not limited to the aforementioned effects.

### BRIEF DESCRIPTION OF THE DRAWINGS

FIG. 1 is a schematic diagram for illustrating a substrate processing apparatus according to one embodiment of the present invention.

FIG. 2 is a schematic diagram for illustrating an example of the configuration of the electrostatic chuck current control circuit unit in the substrate processing apparatus.

FIG. 3 is a schematic diagram for illustrating an example of the electrostatic chuck current control circuit unit 160 of FIG. 2.

FIG. 4 is a schematic diagram for illustrating a flow of an RF current when a plasma power is applied in the substrate processing apparatus of FIG. 1.

### DETAILED DESCRIPTION

Throughout the specification, it should be appreciated that when an element such as a film, an area, a substrate or the like is referred to as being “on” another element, the element may be directly contacted “on” it or there may be other components intervening between them. On the other hand, when an element is referred to as being “directly on” another element, it is interpreted that there are no other elements intervening therebetween.

Herein, embodiments of the present invention will be described with reference to the drawings which schematically illustrates some ideal embodiments of the present invention. In the drawings, for example, modifications of the shapes shown in the drawings may be expected depending on the manufacturing technique and/or tolerance. Accordingly, embodiments of the present inventive concept should not be construed as limited to specific shapes within the range shown herein, but should be construed to include, for example, variations in shape resulting from manufacturing. Further, the thickness and the size of each layer in the drawings may be exaggerated for convenience and clarity of explanation. Also, identical numbers refer to identical elements, respectively.

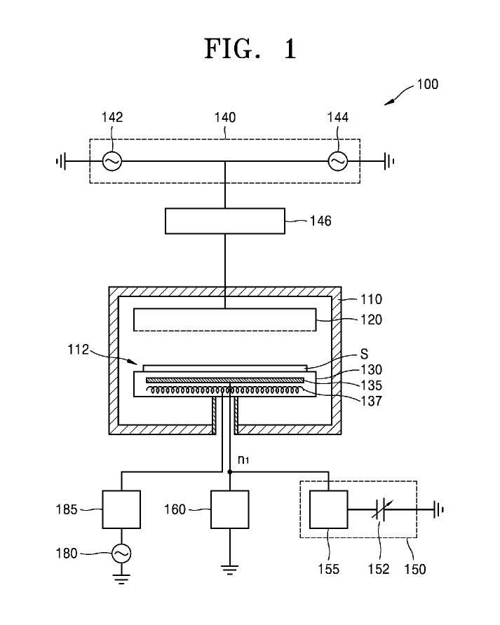

FIG. 1 is a schematic diagram for illustrating a substrate processing apparatus 100 according to one embodiment of the present invention.

Referring to FIG. 1, the substrate processing apparatus 100 may include a process chamber 110, a gas injection unit 120, and an electrostatic chuck 130.

The process chamber 110 may define a process space 112 therein. For example, the process chamber 110 may be configured to be hermetic and connected to a vacuum chamber (not shown) through an exhaust port so as to exhaust a process gas out of the process space 112 and control the degree of vacuum in the process space 112. The process chamber 110 may be provided in various shapes and include, for example, a sidewall portion defining the process space 112 and a lid portion located at the top of the sidewall portion.

The gas injection unit 120 may be provided in the process chamber 110 to supply the process gas supplied from the outside of the process chamber 110 into the process space 112. The gas injection unit 120 may be installed to be opposite to the electrostatic chuck 130 at the top of the process chamber 110 to inject the process gas onto the substrate S placed on the electrostatic chuck 130. The gas injection unit 120 may include at least one inlet hole which is formed on an upper or side portion thereof for receiving the process gas from the outside, and a plurality of injection holes (not shown) which are downwardly formed in a direction facing the substrate S for spraying the process gas onto the substrate S.

For example, the gas injection unit 120 may have various shapes such as a showerhead shape, a nozzle shape, and the like. When the gas injection unit 120 is in the form of a showerhead, the gas injection unit 120 may be coupled to the process chamber 110 in a manner to cover the top of the process chamber 110. For example, the gas injection portion 120 may be coupled to the sidewall portion in the form of a lid of the process chamber 110.

The electrostatic chuck 130 is installed in the process chamber 110 to be opposite to the gas injection unit 120, and the substrate S may be seated thereon. For example, the electrostatic chuck 130 may include an electrostatic electrode 135 for applying an electrostatic force to the substrate S to fix the substrate thereon. An electrostatic power supply unit 150 may include a DC power supply 152 to supply DC power to the electrostatic electrode 135. For example, the DC power supply 152 may be installed such that one end of the DC power supply 152 is connected to the ground and the other end of the DC power supply 152 is electrically connected to the electrostatic electrode 135 via a node n1.

In addition, when the electrostatic power supply unit 150 and an electrostatic chuck current control circuit unit 160 share the node n1 and are connected to the electrostatic electrode 135 in parallel, the electrostatic power supply unit 150 may include a DC filter 155 which is disposed between the electrostatic electrode 135 and the DC power supply 152 to block a RF current flowing through the electrostatic electrode 135 from entering the DC power supply 152. For example, the DC filter 155 may be connected in series between the node n1 and the DC power supply 152. Optionally, a resistor may be added between the DC filter 155 and the node n1. The DC filter 155 may be configured in various forms to pass a DC current while blocking the RF current.

Although the shape of the electrostatic chuck 130 may generally correspond to the shape of the substrate S, it is not limited thereto and may be provided in a variety of shapes that are larger than the substrate S so that the substrate S can be stably mounted. In one example, the electrostatic chuck 130 may be connected to an external motor (not shown) to be able to move up and down. In this case, a bellows pipe (not shown) may be connected thereto to maintain the airtightness. Further, since the electrostatic chuck 130 is configured to house the substrate S thereon, it may also be referred to as a substrate mount portion, a substrate support, a susceptor, or the like.

A plasma power supply unit 140 may include at least one RF power source to apply at least one radio frequency (RF) power to the process chamber 110 to form a plasma atmosphere within the process chamber 110. For example, the plasma power supply unit 140 may be connected to apply RF power to the gas injection unit 120. In this case, the gas injection unit 120 may be referred to as a power supply electrode or an upper electrode. An impedance matching unit 146 may be disposed between the plasma power supply unit 140 and the gas injection unit 120 for impedance matching between the RF power source and the process chamber 110.

The RF power supply in the plasma power supply unit 140 may be one or plural. For example, in order to control the plasma environment in accordance with process conditions, the RF power source may include a first RF power source 142 having a first frequency band and a second RF power source 144 having a second frequency band that is greater than the first frequency band. The dual frequency power source including the first RF power source 142 and the second RF power source 144 has a merit that the process can be precisely controlled since the frequency band can be varied according to process conditions or process steps. Although the plasma power supply unit 140 is illustrated to have two RF power supplies 142 and 144, this is one example and the present invention is not limited thereto.

In one example of the plasma power supply unit 140, the first RF power supply 142 may be a low frequency (LF) power supply including a first frequency band of at least 370 kHz, and the second RF power supply 144 may be a high frequency (HF) power source including a second frequency band of at least 27.12 MHz. The high frequency (HF) power source may be an RF power source in the frequency range of 5 MHz to 60 MHz, optionally, 13.56 MHz to 27.12 MHz. The low frequency (LF) power source may be an RF power source in the frequency range of 100 kHz to 5 MHz, optionally, 300 kHz to 600 kHz. In one embodiment, the second frequency band may have a frequency range from 13.56 MHz to 27.12 MHz, and the first frequency band may have a frequency range from 300 kHz to 600 kHz.

The RF power supplied from the plasma power supply unit 140 can be effectively transferred to the process chamber 110 without being reflected and turned back from the process chamber 110 only when it is subject to an appropriate impedance matching through the impedance matching unit 146 between the plasma power supply unit 140 and the process chamber 110. Generally, since the impedance of the plasma power supply unit 140 is fixed and the impedance of the process chamber 110 is not constant, the impedance of the impedance matching unit 146 may be set to match the impedance of the process chamber 110 with the impedance of the plasma power supply unit 140. However, the scope of the present invention is not limited thereto.

For example, the impedance matching unit 146 may be composed of two or more series or parallel combinations selected from the group consisting of a resistor R, an inductor L and a capacitor C. Further, the impedance matching unit 146 may adopt a variable capacitor or a capacitor array switching structure so that the impedance value thereof can be varied according to the frequency of the RF power and the process conditions.

The electrostatic chuck current control circuit unit 160 may be connected to the electrostatic chuck 130 to control the plasma atmosphere between the gas injection unit 120 and the electrostatic chuck 130. This electrostatic chuck current control circuit unit 160 may be provided for controlling plasma characteristics on the substrate S by controlling the ratio of the RF current on the sidewalls of the process chamber 130 and the RF current onto the electrostatic chuck 130 or the substrate S on the premise of the condition where the impedance matching between the plasma power supply unit 140 and the process chamber 130 is completed, and thus distinguished from the impedance matching unit 146 for impedance matching between the plasma power supply unit 140 and the process chamber 110. In addition, as a comparison example, a lower impedance matching unit may be added between the electrostatic chuck 130 and a lower RF power source (not shown) for the impedance matching therebetween when RF power is applied to the electrostatic chuck 130 instead of the gas injection unit 120. The electrostatic chuck current control circuit unit 160 can also be distinguished from the lower impedance matching unit.

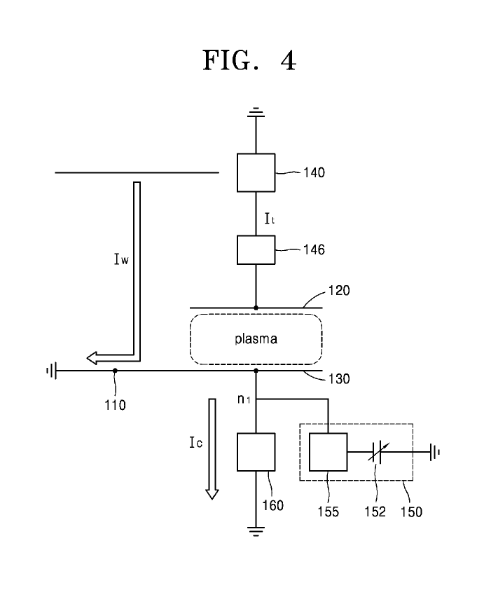

More particularly, as shown in FIG. 4, when RF power is supplied from the plasma power supply unit 140 to the gas injection unit 120, RF power is supplied to the process chamber 110 via the impedance matching unit 146 so that a RF current It flows from the plasma power supply unit 140 to the gas injection unit 120. This RF current It may be divided into a RF current Iw, which flows to a wall surface of the process chamber 110 through the plasma in the process chamber 120, and a RF current Ic, which flows to the electrostatic chuck 130 through the plasma in the process chamber 110.

Since the substrate S is placed on the electrostatic chuck 130, it is required to control the plasma characteristics, for example, such as plasma density, uniformity, shape, and the like in order to increase the processing efficiency when depositing a film on the substrate S or etching a film on the substrate S. To this end, it is required to control the ratio of the RF current Iw flowing to the wall surface of the process chamber 110 and the RF current Ic flowing to the static chuck 130. Since the sum of the two RF currents Iw and Ic is constant, it is needed to adjust the impedance on the path from the electrostatic chuck 130 to the ground in order to adjust the RF current Ic. The electrostatic chuck current control circuit unit 160 can control the RF current Ic flowing to the electrostatic chuck 130 by adjusting the impedance on the path from the electrostatic chuck 130 to the ground.

For example, if the RF current Iw flowing to the wall surface of the process chamber 110 becomes excessively large, the plasma would be dispersed to the periphery of the substrate S to deteriorate the uniformity of the plasma, so that the uniformity of deposited films or etched films on the substrate S could be deteriorated. However, if the RF current Ic is increased by increasing the plasma density on the electrostatic chuck 130 or the substrate S through the electrostatic chuck current control circuit unit 160, the uniformity of the deposited films and the uniformity of the etched films can be increased. Therefore, it is possible to control the plasma characteristics on the electrostatic chuck 130 or the substrate S by controlling the electrostatic chuck current control circuit unit 160.

For example, the electrostatic chuck current control circuit unit 160 may be connected in parallel to the electrostatic power supply unit 150 between the electrostatic electrode 135 and the ground. For example, the electrostatic chuck current control circuit unit 160 and the electrostatic power supply unit 150 may be connected to each other at the node n1 to electrically connected to the electrostatic electrode 135. By connecting with the shared structure mentioned above, the wiring structure connected to the electrostatic electrode 135 can be simplified and the volume of the electrostatic electrode 135 can be thus reduced.

In this parallel connection structure, it is required that the RF current generated by the RF power sources 142 and 144 and flowing through the electrostatic electrode 135 passes through the electrostatic chuck current control circuit unit 160, and the DC current transmitted from the electrostatic power supply unit 150 and flowing into the electrostatic chuck current control circuit unit 160 through the node n1 is blocked. To this end, the electrostatic chuck current control circuit unit 160 may include at least one RF filter for passing the RF current and at least one DC blocking element for blocking the DC current. The DC blocking element may not only be provided separately from the RF filter, but may also include some elements in the RF filter.

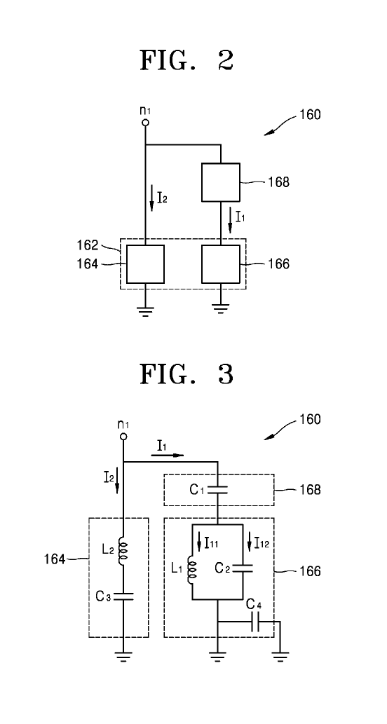

FIG. 2 is a schematic diagram for illustrating an example of the configuration of the electrostatic chuck current control circuit unit in the substrate processing apparatus.

Referring to FIG. 2, the electrostatic chuck current control circuit unit 160 may include an RF filter 162 and a DC blocking element 168. When the power source in the plasma power supply unit 140 includes the first RF power source 142 and the second RF power source 144, the RF filter 162 may include a first RF filter 166 for passing a first RF current I1 having at least a first frequency band, and a second RF filter 164 for passing a second RF current I2 having at least a second frequency band. Since the RF current may include an RF current of a harmonic component besides the RF currents of the first frequency band and the second frequency band, the first RF filter 162 or the second RF filter 164 is required to pass the RF current of the harmonic component in addition to the first frequency band and the second frequency band.

When the first RF filter 166 passes the RF current of the first frequency band (low frequency, LF), the DC blocking element 168 may be connected in series between the node n1 and the first RF filter 166. When the second RF filter 164 is configured to pass the RF current of the second frequency band (high frequency, HF) and block the low frequency band, the second RF filter 164 can block the DC current and additional connection of the DC blocking element can be omitted. In this case, it may also be understood that the DC blocking element is embedded in the second RF filter 164.

For example, the first RF filter 166 may include a band rejection filter (BRF) for passing the first RF current I1 of the first frequency band (low frequency, LF) and the harmonic component, and the second RF filter 164 may include a band pass filter (BPF) that cuts off the DC current while passing the second RF current I2 of a second frequency band (high frequency, HF). This band rejection filter (BRF) may be referred to as a notch filter in that it blocks only a specific frequency band and passes all the remaining components. For example, the first RF filter may be configured as a band rejection filter that blocks the second frequency band HF and passes the rest. Meanwhile, the first RF filter 166 may be referred to as a dual bandpass filter in that it passes both of a frequency band lower than the second frequency band HF and a frequency band higher than the second frequency band HF.

FIG. 3 is a schematic diagram for illustrating an example of the electrostatic chuck current control circuit unit 160 of FIG. 2.

Referring to FIG. 3, the DC blocking element 168 may include a first capacitor C1, and the first RF filter 166 may include a first inductor L1 and a second capacitor C2 which are connected in parallel with each other. Moreover, the first RF filter 166 may further include a fourth capacitor C4 which is connected in series between the ground and the parallel connection structure of the first inductor L1 and the second capacitor C2. For example, the parallel connection structure of the first inductor L1 and the second capacitor C2 may be connected in series with the first capacitor C1.

In the first RF filter 166, the RF current I11 which is lower than the second frequency band HF may flow through the first inductor L1 to the ground, and the RF current I12 which is a harmonic component higher than the second frequency band HF may flow through the second capacitor C2 and the fourth capacitor C4 to the ground.

The second RF filter 164 may include a second inductor L2 and a third capacitor C3 which are connected in series with each other. For example, the second inductor L2 may be connected to the node n1, and the third capacitor C3 may be connected in series between the second inductor L2 and the ground. The second RF filter 164 may be configured to pass the second RF current I2 of the second frequency band HF.

In one embodiment, the third capacitor C3 may be provided as a variable capacitor to be able to adjust the impedance of the second RF filter 164. In an additional embodiment, a sensor (not shown) for detecting the amount of the second RF current I2 flowing to the second RF filter 164 may be further added to the electrostatic chuck current control circuit unit 160. In this case, the second RF current I2 may be detected using the sensor, and the capacitance of the third capacitor C3 may be adjusted based on the detected value in order that the second RF current I2 becomes a desired value.

Furthermore, the capacitance of the third capacitor C3 may be adjusted to measure the film characteristics, e.g., profile, uniformity, etc., on the substrate S after completion of the deposition or etching process so as to obtain desired film characteristics according to the measurement result.

Therefore, according to the aforementioned embodiment, by forming the dual RF filter structure in the electrostatic chuck current control circuit unit 160 in correspondence with the dual RF power source of the high frequency power source and the low frequency power source, it is possible to more precisely control the process characteristic.

Meanwhile, referring again to FIG. 1, the electrostatic chuck 130 may include a heater 17 for heating the substrate S. A heater power supply unit 180 may be connected to the heater 17 so as to apply AC power to the heater 17. Further, a third RF filter 185 may be connected between the heater power supply 180 and the heater 137 to carry out an impedance matching function between the AC power of the heater power supply 180 and the heater 137.

As described above, in the aforementioned embodiments, it is possible to improve the process efficiency (e.g., deposition rate, etching rate, etc.) or process uniformity (e.g., deposition uniformity, etching uniformity, etc.) by controlling the plasma atmosphere or the plasma characteristics on the electrostatic chuck 130 or the substrate S through the electrostatic chuck current control circuit unit 160. Also, by connecting the electrostatic power supply unit 150 and the electrostatic chuck current control circuit unit 160 in parallel at the node n1 so that they can be connected to the electrostatic electrode 135 with a single wiring, it is possible to make the wiring structure at the electrostatic chuck 130 end simple while configuring the circuit such that the RF current and the DC current do not interfere with each other.

While the present invention has been described with reference to the exemplary embodiments shown in the drawings, it should be understood that the embodiments are merely illustrated as examples and a person skilled in the art could made various modifications and other equivalent variations. Therefore, it should be appreciated that the substantial technical scope of the present invention must be constructed based on the technical spirit of the appended claims.

What is claimed is:

1. A substrate processing apparatus, comprising:
a process chamber which defines a process space therein;
a gas injection unit which is installed in the process chamber and supplies a process gas to the process space;
an electrostatic chuck which is installed in the process chamber to be opposite to the gas injection unit and includes an electrostatic electrode for applying electrostatic force to a substrate mounted on the electrostatic chuck;
a plasma power supply unit which includes at least one RF power source for applying at least one RF power to the gas injection unit in order to form a plasma atmosphere within the process chamber;
an impedance matching unit which is connected between the plasma power supply unit and the gas injection unit for impedance matching between the at least one RF power source and the process chamber;
an electrostatic power supply unit which includes a DC power source to supply DC power to the electrostatic electrode; and
an electrostatic chuck current control circuit unit which is connected to the electrostatic electrode in parallel with the electrostatic electrode power supply unit, and passes at least one RF power current which is generated by the at least one RF power source and flows through the electrostatic electrode, while blocking DC current flowed thereinto from the electrostatic power supply unit, in order to control a plasma atmosphere between the gas injection unit and the electrostatic chuck.

2. The substrate processing apparatus according to claim 1,
wherein the electrostatic chuck current control circuit unit includes at least one RF filter for passing the at least one RF current and at least one DC blocking element for blocking the DC current.

3. The substrate processing apparatus according to claim 1,
wherein the at least one RF power source includes a first RF power source of a first frequency band, and a second RF power source of a second frequency band which is greater than the first frequency band, and
the electrostatic chuck current control circuit unit includes a first RF filter for passing at least a first RF current of the first frequency band, a second RF filter for passing at least a second RF current of the second frequency band, and at least one capacitor for blocking the DC current.

4. The substrate processing apparatus according to claim 3,
Wherein the first RF power source is a low frequency (LF) power source in which the first frequency band includes at least 370 kHz,
the second RF power source is a high frequency (HF) power source in which the second frequency band includes at least 27.12 MHz,
the at least one capacitor includes a first capacitor which is connected in series between the electrostatic electrode and the first RF filter, and
the serial connection structure of the first RF filter and the first capacitor is connected in parallel with the second RF filter.

5. The substrate processing apparatus according to claim 4,
wherein the first RF filter includes a band rejection filter for passing the remaining RF current except for the second RF current, and
the second RF filter includes a bandpass filter for blocking the DC current while passing the second RF current.

6. The substrate processing apparatus according to claim 5,
wherein the first RF filter includes a first inductor and a second capacitor which are connected in parallel to each other, and
the second RF filter includes a second inductor and a third capacitor which are connected in series with each other.

7. The substrate processing apparatus according to claim 6,
wherein the first RF filter includes a fourth capacitor which is connected in series between the ground and the parallel connection structure of the first inductor and the second capacitor.

8. The substrate processing apparatus according to claim 4,
wherein the second frequency band has a frequency range from 13.56 MHz to 27.12 MHz, and the first frequency band has a frequency range from 300 kHz to 600 kHz.

9. The substrate processing apparatus according to claim 1,
wherein the electrostatic power supply unit includes a DC filter which is disposed between the electrostatic electrode and the DC power source to block the at least one RF current through the electrostatic electrode from entering the DC power source.

10. The substrate processing apparatus according to claim 1,
wherein the electrostatic chuck includes a heater for heating the substrate, and
a heater power source which is connected to the heater to apply AC power to the heater and a third RF filter which is connected between the heater power source and the heater are further provided.
